(19) United States
(12) Patent Application Publication
(10) Pub. No.: US 2019/0003775 A1
(43) Pub. Date: Jan. 3, 2019

(54) ANTI-BENDING HEAT DISSIPATION MODULE

(71) Applicant: TAIWAN MICROLOOPS CORP., New Taipei City (TW)

(72) Inventor: Chun-Hung LIN, New Taipei City (TW)

(21) Appl. No.: 15/638,134

(22) Filed: Jun. 29, 2017

(51) Int. Cl. F28D 9/00; H05K 7/20

(52) U.S. Cl. CPC F28D 9/0062; F28D 9/0006; H05K 7/209

(57) ABSTRACT

An anti-bending heat dissipation module includes a vapor chamber, a heat dissipation fin set and an anti-bending component. The vapor chamber includes a case and a chamber formed in the case. The heat dissipation fin set is fixed on a surface of the case. The anti-bending component is arranged between the case and the heat dissipation fin set and is pressedly connected on the case.

Thereby it can effectively prevent a vapor chamber from bending and deforming.

### BACKGROUND OF THE INVENTION

### 1. Technical Field

The invention relates to technology of heat dissipation modules, particularly to an anti-bending heat dissipation module.

### 2. Related Art

With continuous increase of computing speed of electronic components, heat generated therefrom also becomes higher and higher. To effectively solve this problem of high heat, vapor chambers with great thermal conductivity have been widely applied by the industry. A vapor chamber not only has a wide heated area to be directly attached by a heat source, but also has advantages of light weight and fast heat transferring speed. The heat transferring speed of a vapor chamber is above ten times as quick as that of a copper-based cooler. Thus heat dissipation with a vapor chamber has become a necessary component for electronic heat sources.

However, current heat dissipation modules with a vapor chamber applied in an electronic heat source are always fixed by screws or fasteners. Because a vapor chamber is a hollow structure, it is easy to be bent or deformed when it is fixed on a circuit board by screws. Not only is a heated surface of a vapor chamber hard to be completely tightly attached on an electronic heat source, but also the heat dissipation fins fixed on a cooling surface of the vapor chamber tend to be peeled off or fallen off.

### SUMMARY OF THE INVENTION

An object of the invention is to provide an anti-bending heat dissipation module, which can effectively prevent a vapor chamber from bending and deforming by using an anti-bending component to press the vapor chamber.

To accomplish the above object, the invention provides an anti-bending heat dissipation module including a vapor chamber, a heat dissipation fin set and an anti-bending component. The vapor chamber includes a case and a chamber formed in the case. The heat dissipation fin set is fixed on a surface of the case. The anti-bending component is arranged between the case and the heat dissipation fin set and is pressedly connected on the case.

The invention further has following advantages. By using an anti-bending component to press a middle region of the first side length, the best effect of anti-bending can be obtained. By arranging a fixing frame, every corner and middle region of a vapor chamber can be equally pressed so that the structural completeness of a vapor chamber can be kept when it has been assembled.

### BRIEF DESCRIPTION OF THE DRAWINGS

FIG. 1 is a perspective view of the heat dissipation module of the invention;

FIG. 2 is an assembled view of the heat dissipation module of the invention;

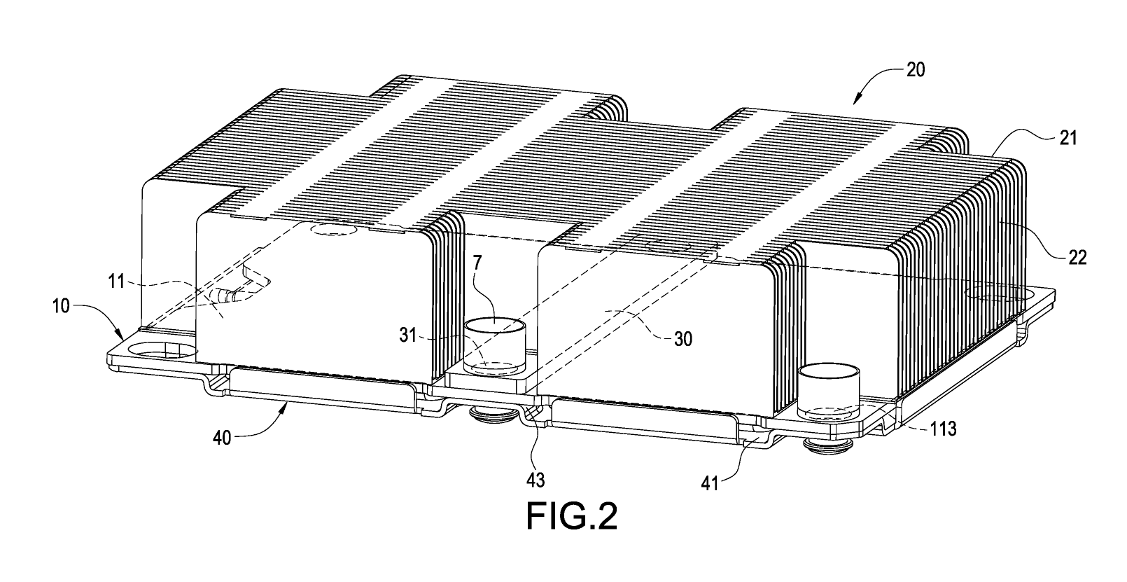

FIG. 3 is another assembled view of the heat dissipation module of the invention;

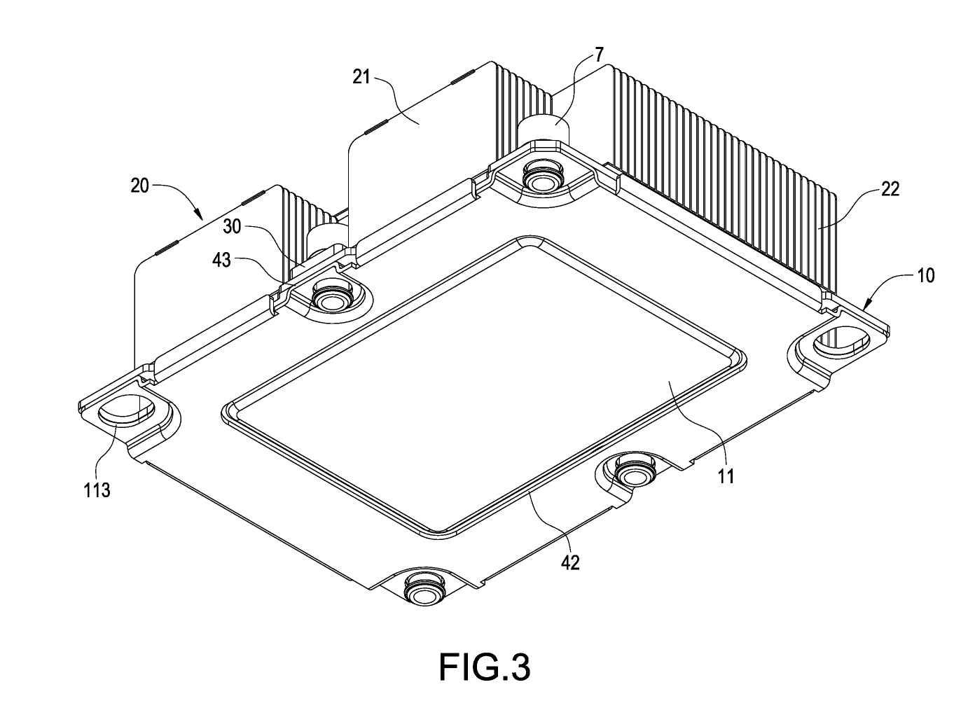

FIG. 4 is a cross-sectional view of the heat dissipation module of the invention; and

FIG. 5 is a cross-sectional view of another embodiment of the heat dissipation module of the invention.

### DETAILED DESCRIPTION OF THE INVENTION

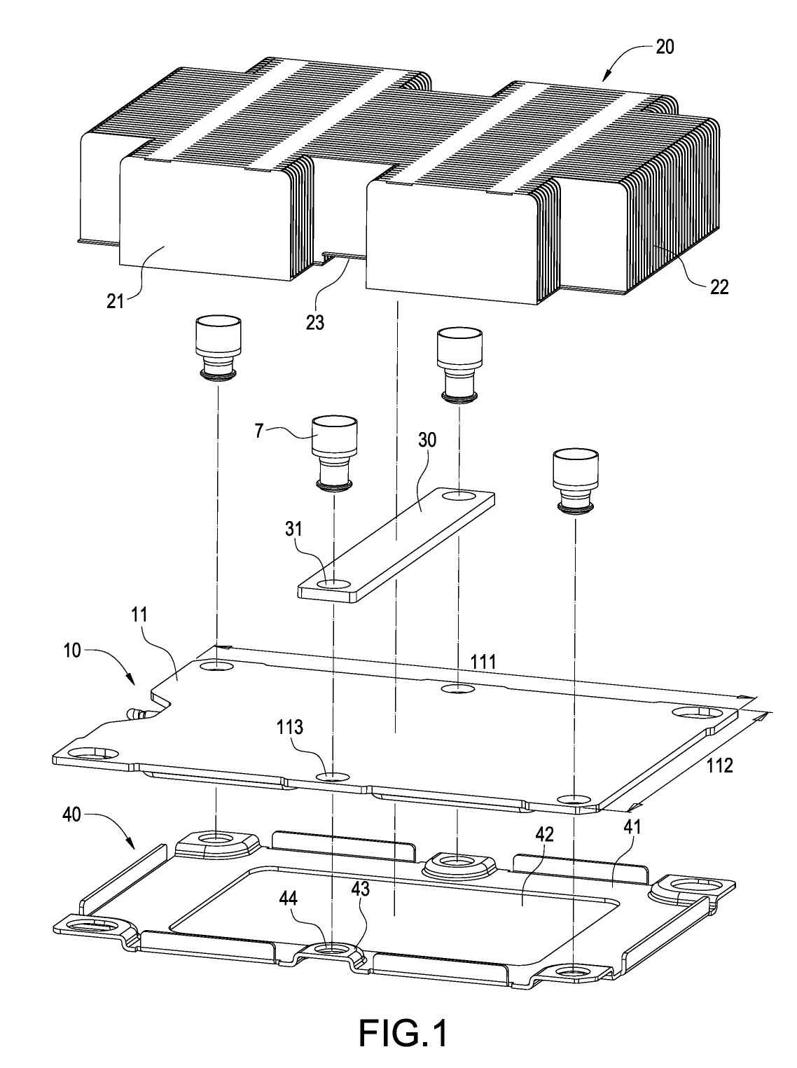

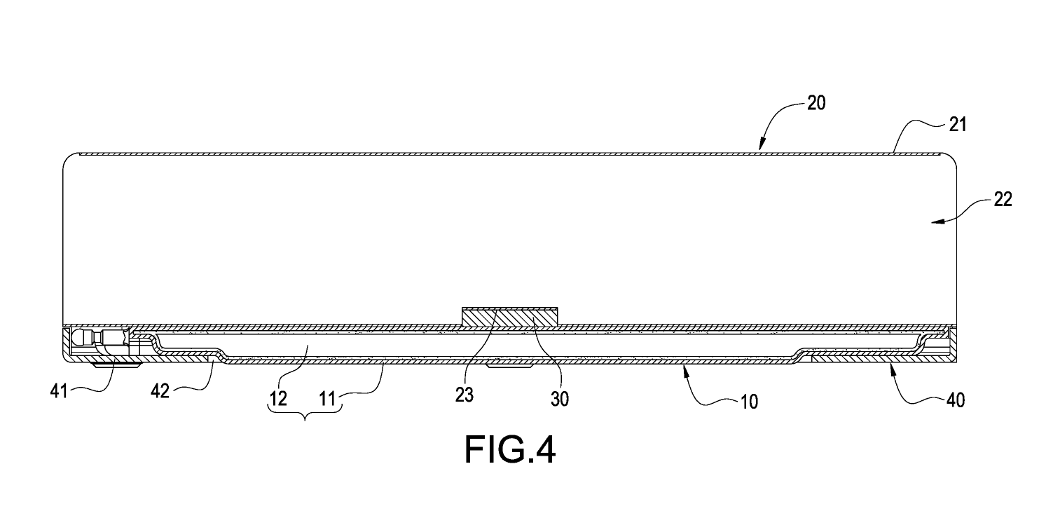

Please refer to FIGS. 1 and 4. The invention provides an anti-bending heat dissipation module, which includes a vapor chamber 10, a heat dissipation fin set 20 and an anti-bending component 30. The vapor chamber 10 includes a case 11 and a chamber 12 formed in the case 11. The case 11 is made of a material with great thermal conductivity, such as copper, aluminum or their alloy. In this embodiment, the case 11 is approximately rectangular in shape. The case 11 includes a first side length 111 and a second side length 112 which is perpendicular to the first side length 111. The first side length 111 is great than the second side length 112. Each corner and the edge position of a middle region of the case 11 are separately provided with a through hole 113. Also, the chamber 12 of the case 11 is disposed with a wick structure formed by a metal woven mesh, fiber bundles or sintered metal powder. A working fluid (not shown) is injected into the chamber 12.

The heat dissipation fin set 20 is fixed on a surface of the case 11 by soldering or welding. The heat dissipation fin set 20 includes a plurality of heat dissipation fins 21 which is made of a material with great thermal conductivity such as copper, aluminum or their alloy. The heat dissipation fin set 20 is formed by parallelly stacking up the heat dissipation fins 21. A heat dissipation passage 22 is formed between two adjacent heat dissipation fins 21. In this embodiment, a receiving trough 23 is arranged under the middle region of the heat dissipation fin set 20.

The anti-bending component 30 is made of stainless steel with high rigidity and is arranged between the case 11 and the heat dissipation set 20 with being perpendicular to the first side length 111. In this embodiment, the anti-bending component 30 passes the receiving trough 23 and is pressedly connected the middle position of the first side length 111 of the case 11. Each of two ends of the anti-bending component 30 is provided with a passing hole 31 separately corresponding to the through holes 113.

Furthermore, the anti-bending heat dissipation module of the invention includes a fixing frame 40 which is arranged under the case 11. The fixing frame 40 includes a frame body 41 whose outline is approximately similar to the shape of the vapor chamber 10. The middle position of the frame body 41 is formed with a hollow 42 for receiving a part of the vapor chamber 10. Each corner and the middle region of the frame body 41 are separately extended with a protrusion portion 43. Each protrusion portion 43 is formed with a fixing hole 44 separately corresponding to the through holes 113.

When assembling, a bolt 7 passes through the passing hole 31 of the anti-bending component 30 and the through hole 113 of the vapor chamber 10 so as to make the anti-bending component 30 pressedly connected on the middle position of the case 11. Next, the bolt 7 further passes through the fixing hole 44 of the fixing frame 40. Another bolt 7 passes through the through hole 113 of the vapor chamber 10 and the fixing hole 44 of the fixing frame 40 for fastening so as to integrate the vapor chamber 10, the heat dissipation fin set 20 and the fixing frame 40 into a combination.

When using the anti-bending heat dissipation module, attach the bottom of the vapor chamber 10 onto an upper surface of a heat source (not shown) and use fasteners (not shown) such as screws to pass through holes of a circuit board (not shown) of the heat source to screw up a bottom section of the bolt 7. Because the middle position of the vapor chamber 10 is pressedly connected by the anti-bending component 30, two ends of the rectangular case 11 can be prevented from bending or deforming when the corners of the vapor chamber 10 are being fastened.

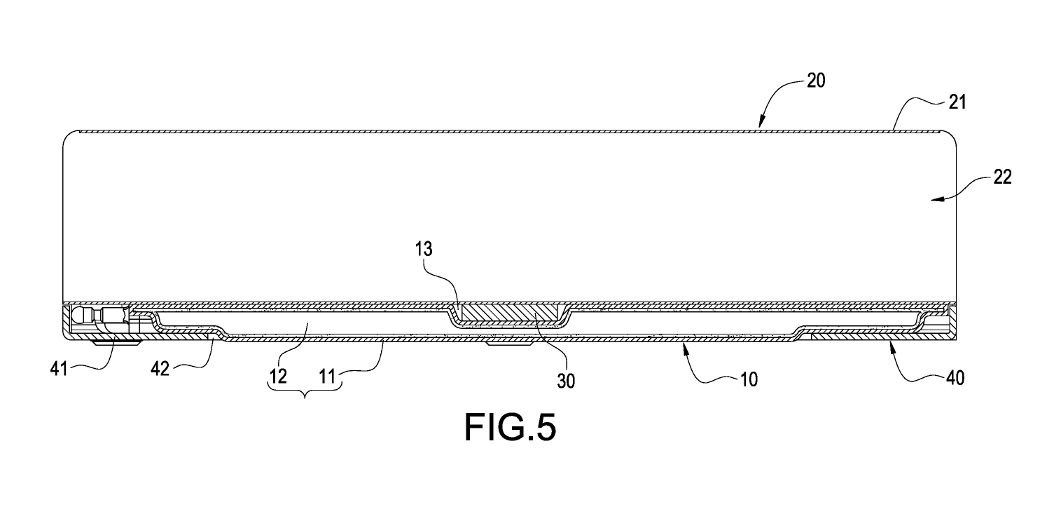

Please refer to FIG. 5. Besides the above embodiment, the invention also provides another embodiment. This embodiment differs from the above embodiment by a channel 13 formed in the middle position of the case 11. The anti-bending component 30 passes through the channel 13 and pressedly connects to the middle region of the case 11. This can also accomplish the same effect as the above embodiment.

It will be appreciated by persons skilled in the art that the above embodiments have been described by way of example only and not in any limitative sense, and that various alterations and modifications are possible without departure from the scope of the invention as defined by the appended claims.

1. An anti-bending heat dissipation module comprising:
a vapor chamber comprising a case and a chamber formed in the case, wherein the case is formed in a rectangle shape;
a fixing frame disposed under the vapor chamber, an outline of the fixing frame approximating to a shape of the vapor chamber;
a heat dissipation fin set fixed on a surface of the case; and
an anti-bending component, arranged between the case and the heat dissipation fin set, and pressedly connected on the case,
wherein the case comprises a first side and a second side perpendicular to the first side, a length of the first side is greater than a length of the second side, and a length of the anti-bending component is no shorter than the length of the second side.

2. (canceled)

3. The anti-bending heat dissipation module of claim 1, wherein the anti-bending component is arranged perpendicularly to the first side.

4. The anti-bending heat dissipation module of claim 3, wherein the anti-bending component is pressedly connected to a middle position of the first side length.

5. The anti-bending heat dissipation module of claim 1, wherein the heat dissipation fin set is formed by parallelly stacking up heat dissipation fins, and a heat dissipation passage is formed between two adjacent heat dissipation fins.

6. The anti-bending heat dissipation module of claim 5, wherein a receiving trough is arranged under the heat dissipation fin set for receiving the anti-bending component.

7. The anti-bending heat dissipation module of claim 1, wherein a channel is formed in a middle position of the case for receiving the anti-bending component.

8. (canceled)

9. The anti-bending heat dissipation module of claim 1, wherein two middle edges of the case are separately provided with a through hole, each of two ends of the anti-bending component is provided with a passing hole separately corresponding to the through holes for being passed by a bolt.

10. The anti-bending heat dissipation module of claim 9, wherein each corner of the case is provided with a through hole, the fixing frame comprises a frame body, a middle position of the frame body is formed with a hollow for receiving a part of the case, each corner of the frame body is separately extended with a protrusion portion, each protrusion portion is formed with a fixing hole separately corresponding to the through holes for being passed by a bolt.

11. The anti-bending heat dissipation module of claim 1, wherein the anti-bending component is a stainless steel.
